(19) United States
(12) Patent Application Publication
(10) Pub. No.: US 2012/0313243 A1
(43) Pub. Date: Dec. 13, 2012

(54) CHIP-SCALE PACKAGE

(75) Inventors: Chiang-Cheng Chang, Taichung (TW); Hung-Wen Liu, Taichung (TW); Hsi-Chang Hsu, Taichung (TW); Hsin-Yi Liao, Taichung (TW); Shih-Kuang Chiu, Taichung (TW)

(73) Assignee: SILICONWARE PRECISION INDUSTRIES CO., LTD., Taichung (TW)

(21) Appl. No.: 13/221,323

(22) Filed: Aug. 30, 2011

(30) Foreign Application Priority Data
Jun. 13, 2011 (TW) 100120504

(51) Int. Cl. H01L 23/498; H01L 23/48

(52) U.S. Cl. 257/738; 257/774; 257/737; 257/E23.011; 257/E23.069; 257/E23.068

(57) ABSTRACT

A chip-scale package includes an encapsulating layer, a chip embedded in the encapsulating layer and having an active surface exposed from the encapsulating layer, a buffering dielectric layer formed on the encapsulating layer and the chip, a build-up dielectric layer formed on the buffering dielectric layer, and a circuit layer formed on the build-up dielectric layer and having conductive blind vias penetrating the build-up dielectric layer and being in communication with the openings of the buffering dielectric layer and electrically connected to the chip, wherein the build-up dielectric layer and the buffering dielectric layer are made of different materials. Therefore, delamination does not occur between the buffering dielectric layer and the encapsulating layer, because the buffering dielectric layer is securely bonded to the encapsulating layer and the buffering dielectric layer is evenly distributed on the encapsulating layer.

### BACKGROUND OF THE INVENTION

1. Field of the Invention

This invention relates to semiconductor packages, and, more particularly, to a chip-scale package.

2. Description of Related Art

With the advancement of semiconductor technology, a semicondcutor product may be packaged in a variety of types. In order for the semiconductor package to be low-profiled and compact-sized, a chip-scale package (CSP) is brought to the market. The chip-scale package is characterized in that it is equal to or slightly greater than a chip.

As shown in FIG. 1, a chip-scale package 1 of the prior art comprises a hard board 17 such as a silicon carrier board; an encapsulating layer 10 having a first surface 10a and a second surface 10b opposing the first surface 10a, with the second surface 10b installed on the hard board 17, the encapsulating layer 10 being made of soft material, such as Ajinomoto build-up film (ABF) and bismaleimide-triacine (BT); at least one chip 11 embedded into the first surface 10a of encapsulating layer 10 and having an active surface 11a exposed from the first surface 10a of the encapsulating layer 10 and an inactive surface 11b opposing the active surface 11a; a plurality of electrode pads 110 disposed on the active surface 11a of the chip 11; a build-up dielectric layer 12 made of polyimide (PI) formed on the first surface 10a of the encapsulating layer 10 and the active surface 11a of the chip 11 and having a plurality of openings 120 allowing the electrode pads 110 to be exposed therefrom; and a circuit layer 13 formed on the build-up dielectric layer 12 and having a plurality of conductive blind vias 130 formed in the openings 120 and electrically connected to the electrode pads 110. To meet the product requirements, more build-up dielectric layers may be included in the chip-scale package 1, and a solder layer and solder balls may be disposed on the outermost one of the build-up dielectric layers.

However, in the chip-scale package 1 the material of the build-up dielectric layer 12 suffers a non-wetting problem with respect to the material of the encapsulating layer 10, which results in a poor distribution of the build-up dielectric layer 12. Accordingly, the build-up dielectric layer 12 is not evenly distributed on the encapsulating layer 10.

Moreover, the solvent in the build-up dielectric layer 12 causes damages to the encapsulating layer 10. As a result, the build-up dielectric layer 12 is likely to be delaminated from the encapsulating layer 10 due to their poor adhering property, and the chip-scale package 1 thus has poor reliability.

Therefore, how to overcome the problems of the prior art is becoming one of the most imperative issues in the art.

### SUMMARY OF THE INVENTION

In view of the above-mentioned problems of the prior art, the present invention provides a chip-scale package, comprising: an encapsulating layer having a first surface and a second surface opposing the first surface; at least one chip embedded in the first surface of the encapsulating layer and having an active surface exposed from the first surface of the encapsulating layer, an inactive surface opposing the active surface, and a plurality of electrode pads disposed on the active surface; a buffering dielectric layer formed on the first surface of the encapsulating layer and the active surface of the chip and having a plurality of openings for the electrode pads to be exposed therefrom; a build-up dielectric layer formed on the buffering dielectric layer, the build-up dielectric layer and the buffering dielectric layer being made of different materials; and a circuit layer formed on the build-up dielectric layer and having a plurality of conductive blind vias penetrating the build-up dielectric layer and being in communication with the openings of the buffering dielectric layer and electrically connected to the circuit layer and the electrode pads.

In the chip-scale package, the buffering dielectric layer is made of inorganic silicon material or organic polymer material.

The chip-scale package further comprises a hard layer having a third surface and a fourth surface opposing the third surface. The third surface of the hard layer is attached to the second surface of the encapsulating layer, and the hard layer is harder than the encapsulating layer.

It is known from the above that, in the chip-scale package according to the present invention, the buffering dielectric layer is used to replace the build-up dielectric layer. Since having a good non-wetting property with respect to the encapsulating layer, the buffering dielectric layer is evenly distributed on the encapsulating layer.

Moreover, the solvent in the buffering dielectric layer does not cause damages to the encapsulating layer, and the buffering dielectric layer is adhered to the encapsulating layer securely. Accordingly, delamination does not occur between the buffering dielectric layer and the encapsulating layer, and therefore reliability of the chip-scale package can be effectively improved.

According to the various aspects of the chip-scale package of the present invention, the present invention further provides a variety of embodiments, which will be described in detail in the following paragraphs.

### BRIEF DESCRIPTION OF DRAWINGS

The invention can be more fully understood by reading the following detailed description of the preferred embodiments, with reference made to the accompanying drawings, wherein:

FIG. 1 is a cross-sectional view of a chip-scale package according to the prior art;

FIGS. 2, 2′ and 2″ are cross-sectional views of a chip-scale package of a first embodiment according to the present invention;

FIG. 3 is a cross-sectional view of a chip-scale package of a second embodiment according to the present invention;

FIGS. 4 and 4′ are cross-sectional views of a chip-scale package of a third embodiment according to the present invention;

FIGS. 5 and 5′ are cross-sectional views of a chip-scale package of a fourth embodiment according to the present invention;

FIGS. 6, 6′ and 6″ are cross-sectional views of a chip-scale package of a fifth embodiment according to the present invention;

FIG. 7 is a cross-sectional view of a chip-scale package of a sixth embodiment according to the present invention; and

FIGS. 8, 8′ and 8″ are cross-sectional views of a chip-scale package of a seventh embodiment according to the present invention;

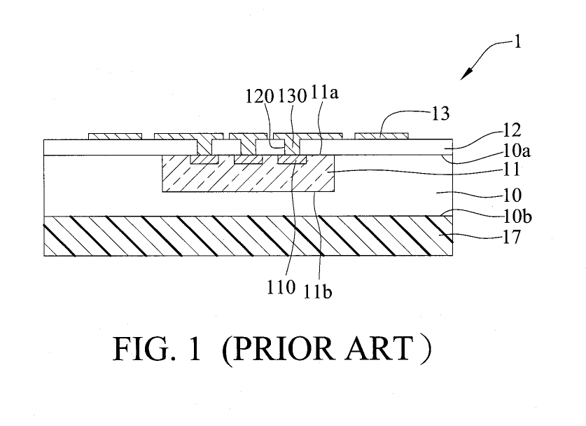

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

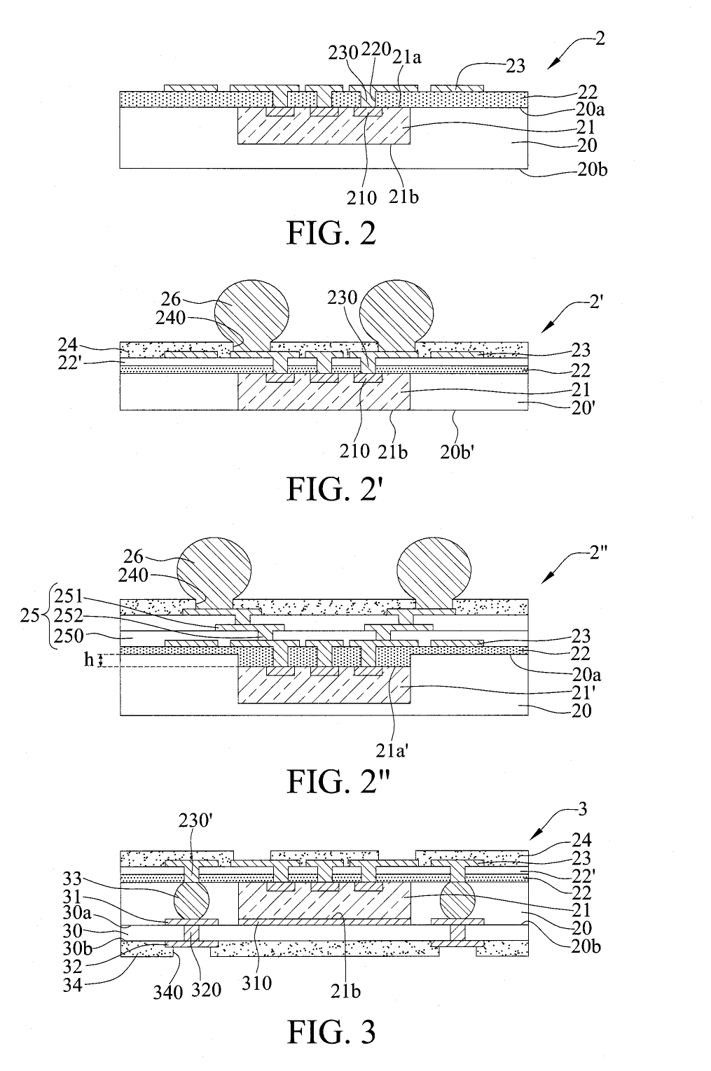

Referring to FIG. 2, a chip-scale package 2 of a first embodiment is shown according to the present invention. The chip-scale package 2 comprises an encapsulating layer 20 having a first surface 20a and a second surface 20b opposing the first surface 20a, at least one chip 21 embedded into the first surface 20a of the encapsulating layer 20 and exposed from the first surface 20a of the encapsulating layer 20, a buffering dielectric layer 22 formed on the first surface 20a of the encapsulating layer 20 and the chip 21, and a circuit layer 23 formed on the buffering dielectric layer.

The encapsulating layer 20 may be made of packaging resin or soft material. In the first embodiment, the soft material is Ajinomoto build-up film (ABF), bismaleimide-triacine (BT), polyimide (PI), polymerized siloxanes (silicone) or epoxy resin.

The chip 21 has an inactive surface 21b and an active surface 21a opposing the inactive surface 21b and exposed from the first surface 20a of the encapsulating layer 20. A plurality of electrode pads 210 are disposed on the active surface 21a of the chip 21. In the first embodiment, the chip 21 is an active element or a passive elements.

The buffering dielectric layer 22 is formed on the first surface 20a of the encapsulating layer 20 and the active surface 21a of the chip 21 by a chemical vapor deposition (CVD) process. A plurality of openings are formed, allowing the electrode pads 210 to be exposed therefrom. In the first embodiment, the buffering dielectric layer 22 is made of an inorganic silicon material, such as SiO₂ and Si₃N₄, or an organic polymer material such as parylene.

Conductive blind vias 230 are formed in the openings 220. The circuit layer 23 is electrically connected through the conductive blind vias 230 to the electrode pads 210.

Referring to FIG. 2′, a build-up dielectric layer 22′ is formed on the buffering dielectric layer 22 first, then the circuit layer 23 is formed on the build-up dielectric layer 22′, and the conductive blind vias 230 further penetrate the build-up dielectric layer 22′ and are electrically connected to the electrode pads 210. The build-up dielectric layer 22′ is made of polyimide (PI), which is different from the material of the buffering dielectric layer 22.

In the package 2′, an insulating protective layer 24 is formed on the buffering dielectric layer 22 and the circuit layer 23, and a plurality of holes 240 are formed on the insulating protective layer 24 for exposing a portion of the circuit layer 23, for conductive elements 26 (e.g., metal wire, solder, and solder balls) to be disposed on the exposed portion of the circuit layer 23 in the holes 240.

Referring to FIG. 2″, in a package 2″ a build-up structure 25 electrically connected to the circuit layer 23 is formed, before the formation of the buffering dielectric layer 22 and the circuit layer 23, and an insulating protective layer 24 with a plurality of holes 240 formed therethrough is then formed on the insulating protective layer 24, for conductive elements 26 electrically connected to the build-up structure 25 to be disposed therein.

The build-up structure 25 comprises at least one build-up dielectric layer 250, another circuit layer 251 formed on the build-up dielectric layer 250, and another conductive blind vias 252 formed in the build-up dielectric layer 250 and electrically connected to the circuit layers 23 and 251.

The second surface 20b′ of the encapsulating layer 20′ may be even with the inactive surface 21b of the chip 21, as shown in FIG. 2′. Alternatively, the first surface 20a of the encapsulating layer 20 may be higher than the active surface 21a′ of the chip 21′, as indicated by a height difference h shown in FIG. 2″.

Since formed by the chemical vapor deposition process, the buffering dielectric layer 22 has good enough distribution and evenness qualities. Accordingly, the buffering dielectric layer 22 is evenly distributed on the encapsulating layer 20 and the chip 21. Therefore, the expansion and evenness of surface between layers is greatly improved.

The buffering dielectric layer 22 is adhered to the build-up dielectric layer 22′ and the encapsulating layer 20 securely, and the solvent in the buffering dielectric layer 22 does not cause damages to the encapsulating layer 20. Therefore, delamination does not occur among the buffering dielectric layer 22, the build-up dielectric layer 22′ and the encapsulating layer 20, and the chip-scale package according to the present invention may have improved reliability.

### Second Embodiment

Referring to FIG. 3, the second embodiment differs from the first embodiment only in that a substrate 30 is further disposed in the second embodiment.

In the package 3, a substrate 30 is disposed on the second surface 20b of the encapsulating layer 20 and the inactive surface 21b of the chip 21.

The substrate 30 has a top surface 30a and a bottom surface 30b. Circuits 31 and 32 connected to each other are formed on the top surface 30a and the bottom surface 30b, respectively. The top surface 30a is attached to the second surface 20b of the encapsulating layer 20 and the inactive surface 21b of the chip 21. The circuit 31 on the top surface 30a is embedded into the encapsulating layer 20. A plurality of conductive elements 33 are disposed on the circuit 31 on the top surface 30a and electrically connected to the conductive blind vias 230′ of the circuit layer 23.

In the second embodiment, the circuits 31 and 32 are electrically connected to each other by conductive through holes 320 that penetrate the substrate 30. Heat-dissipating pads 310 may be disposed on the circuit 31 on the top surface 30a of the substrate 30, depending on demands, for the inactive surface 21b of the chip 21 to be disposed thereon, to dissipate heat generated by the chip 21.

The substrate 30 may have a multiple-layered circuit (not shown) formed therein.

The conductive elements 33 may be solder balls, pins, metal bumps or metal pillars.

In the package 3, an insulating protective layer 34 is formed on the bottom surface 30b of the substrate 30 and the circuit 32. The insulating protective layer 34 has a plurality of holes 340, for a portion of the circuit 32 formed on the bottom surface 30b to be exposed therefrom. Conductive elements (not shown) are allowed to be disposed on the exposed potion of the circuit 32.

### Third Embodiment

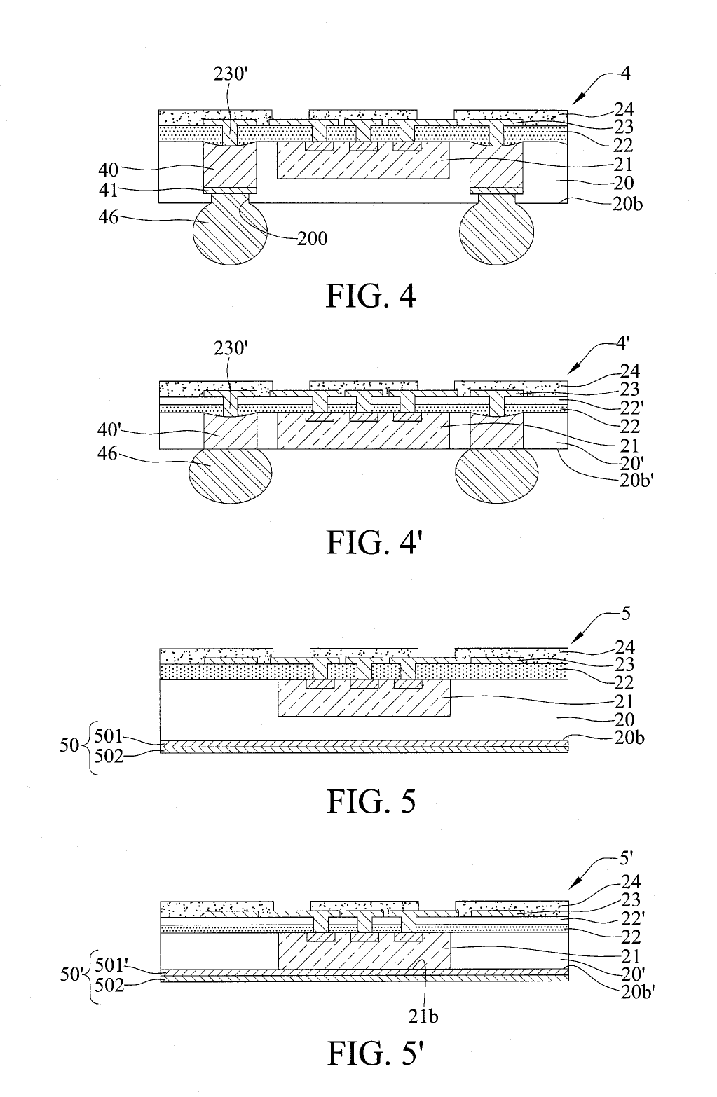

Referring to FIGS. 4 and 4′ the third embodiment differs from the first embodiment only in that conductive bumps 40 and 40′ are further disposed in the chip-scale package of the third embodiment.

In the package 4, 4′, conductive bumps 40, 40′ are disposed in the encapsulating layer 20. The conductive bumps 40, 40′ have top ends combined with the buffering dielectric layer 22 and bottom ends exposed from the second surface 20b, 20b′ of the encapsulating layer 20, 20′, to further combine with conductive elements (e.g., metal wire, solder, solder balls) 46. The circuit layer 23 is electrically connected through the conductive blind vias 230′ to the top ends of the conductive bumps 40, 40′.

In the fourth embodiment, the conductive bumps 40, 40′ are made of copper.

As shown in FIG. 4, a metal layer 41 is formed on the bottom ends of the conductive bumps 40, for the conductive elements 46 to be coupled therewith.

The bottom ends of the conductive bumps 40 are exposed by forming in the encapsulating layer 20 through the second surfaces 20b thereof a plurality of holes 200 that expose the conductive bumps 40, such that the conductive elements 46 are allowed to be electrically connected to the conductive bumps 40 in the hole 240, as shown in FIG. 4. Alternatively, the conductive bumps 40′ are even with the second surface 20b′ of the encapsulating layer 20′, such that the conductive bumps 40′ are exposed from the encapsulating layer 20′ allowing the conductive elements 46 to be electrically connected with the conductive bumps 40′, as shown in FIG. 4′.

### Fourth Embodiment

Referring to FIGS. 5 and 5′, the fourth embodiment differs from the first embodiment only in that a metal structure layer 50, 50′ is further formed in the package 5, 5′.

In the package 5, 5′, the metal structure layer 50 is formed on the second surface 20b, 20b′ of the encapsulating layer 20, 20′.

In the fourth embodiment, the metal structure layer 50 includes a first metal sublayer 501 formed on the second surface 20b, 20b′ of the encapsulating layer 20, 20′ and a second metal sublayer 502 formed on the first metal sublayer 501. The first metal sublayer 501 is made of a chemical plating metal material or a sputtering metal material, and the second metal sublayer 502 is made of an electroplating metal material.

The first metal sublayer 501′ of the metal structure layer 50′ is formed on the inactive surface 21b of the chip 21, as shown in FIG. 5′.

### Fifth Embodiment

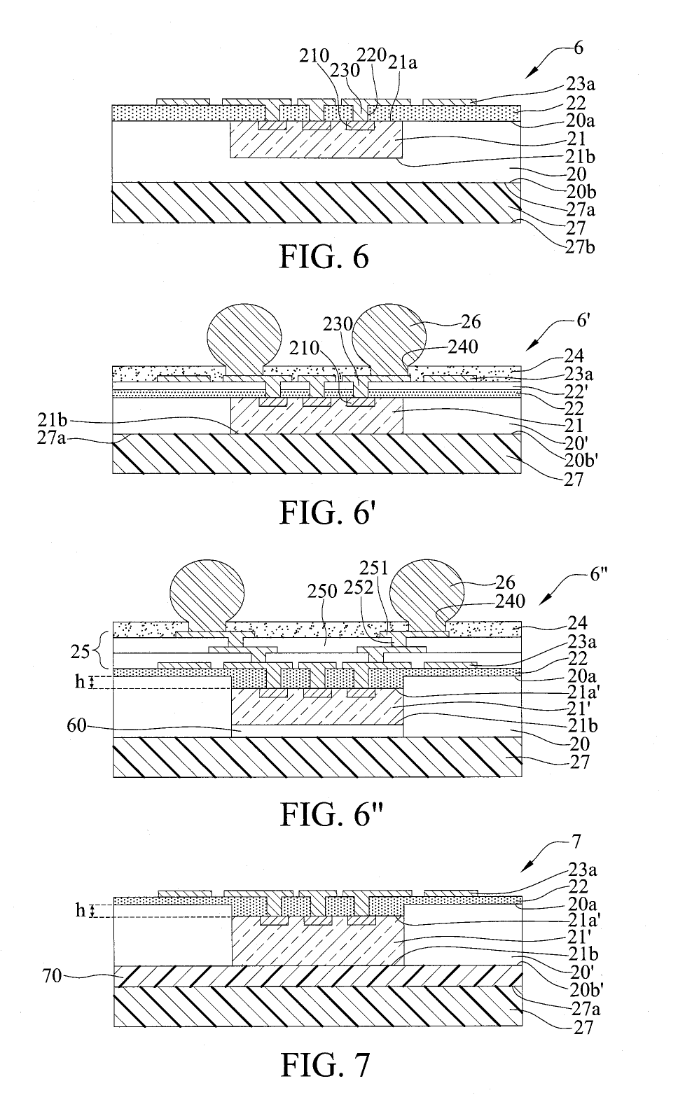

Referring to FIG. 6, the fifth embodiment differs from the first embodiment in that a hard layer 27 is further formed in a chip-scale package 6 of the fifth embodiment.

The chip-scale package 6 comprises an encapsulating layer 20 having a first surface 20a and a second surface 20b opposing the first surface 20a, at least one chip 21 embedded into the first surface 20a of the encapsulating layer 20 and exposed from the first surface 20a of the encapsulating layer 20, a buffering dielectric layer 22 formed on the first surface 20a of the encapsulating layer 20 and the chip 21, a hard layer 27 combined with the second surface 20b of the encapsulating layer 20, and a first circuit layer 23a formed on the buffering dielectric layer 22.

The encapsulating layer 20 is made of packaging resin or soft material. In the fourth embodiment, the soft material is ABF, BT, polyimide, polymerized siloxanes or epoxy resin.

The chip 21 has an active surface 21a and an inactive surface 21b opposing the active surface 21a. A plurality of electrode pads 210 are disposed on the active surface 21a of the chip 21. The chip 21 is disposed with the active surface 21a thereof exposed from the first surface 21a of the encapsulating layer 20. In the fourth embodiment, the chip 21 is an active element or a passive elements.

The buffering dielectric layer 22 is formed on the first surface 20a of the encapsulating layer 20 and the active surface 21a of the chip 21 by a chemical vapor deposition process. Openings 220 are formed through the buffering dielectric layer 22, for the electrode pads 210 to be exposed therefrom. In the fourth embodiment, the buffering dielectric layer 22 is made of an inorganic silicon material such as SiO₂ or Si₃N₄, or an organic polymer material such as parylene.

The hard layer 27 has a third surface 27a and a fourth surface 27b opposing the third surface 27a. The third surface 27a of the hard layer 27 is attached to the second surface 20b of the encapsulating layer 20. The hard layer 27 is harder than the encapsulating layer 20. In the fifth embodiment, the hard layer 27 is made of solder mask material, epoxy resin, epoxy resin-contained ink, polyimide, silicon material, metal, prepreg, or copper foil substrate, and the encapsulating layer 20 differs from the hard layer 27 in at least five times of Young's modulus.

Conductive blind vias 230 are formed in the openings 220, and the first circuit layer 23a is electrically connected through the conductive blind vias 230 to the electrode pads 210.

Referring to FIG. 6′, in the package 6′ a build-up dielectric layer 22′ is formed on the buffering dielectric layer 22 first, and then a first circuit layer 23a is formed on the build-up dielectric layer 22′, wherein the conductive blind vias 230 further penetrate the build-up dielectric layer 22′ and are electrically connected to the electrode pads 210. The build-up dielectric layer 22′ is made of polyimide, which is different from the material of the buffering dielectric layer 22.

In the package 6′, an insulating protective layer 24 is formed on the buffering dielectric layer 22 and the first circuit layer 23a, and a plurality of holes 240 are formed on the insulating protective layer 24 to expose a portion of the first circuit layer 23a. Therefore, the conductive elements 26 are allowed to be disposed on the first circuit layer 23a via the holes 240.

Referring to FIG. 6″, in the package 6″ a build-up structure 25 electrically connected to the first circuit layer 23a is formed on the buffering dielectric layer 22 and the first circuit layer 23a, an insulating protective layer 24 is then formed on the build-up structure 25, and a plurality of holes 240 are formed in the insulating protective layer 24, for conductive elements 26 electrically connected to the build-up structure 25 to be disposed therein.

The build-up structure 25 comprises at least one build-up dielectric layer 250, another circuit 251 formed on the build-up dielectric layer 250, and another conductive blind vias 252 disposed in the build-up dielectric layer 250 and electrically connected to the first circuit layer 23a and the circuit layer 251.

The second surface 20b′ of the encapsulating layer 20′ is even with the inactive surface 21b of the chip 21, and the third surface 27a of the hard layer 27 is further attached to inactive surface 21b of the chip 21, as shown in FIG. 6′. Alternatively, a die attach film 60 is formed between the inactive surface 21b of the chip 21′ and the hard layer 27, as shown in FIG. 6″.

The first surface 20a of the encapsulating layer 20 is higher than the active surface 21a′ of the chip 21′, as indicated by a height difference h shown in FIG. 6″.

### Sixth Embodiment

Referring to FIG. 7, the sixth embodiment differs from the fifth embodiment only in that a reinforced protective layer 70 is further formed in the sixth embodiment.

The reinforced protective layer 70 is formed between the second surface 20b′ of the encapsulating layer 20′ and the third surface 27a of the hard layer 27, and the reinforced protective layer 70 is epoxy resin.

In a package 7 of the sixth embodiment, the second surface 20b′ of the encapsulating layer 20′ is even with the inactive surface 21b of the chip 21′, and the reinforced protective layer 70 is further attached to the inactive surface 21b of the chip 21′. The first surface 20a of the encapsulating layer 20′ is higher than the active surface 21a′ of the chip 21′, as indicated by a height difference h shown in FIG. 7.

### Seventh Embodiment

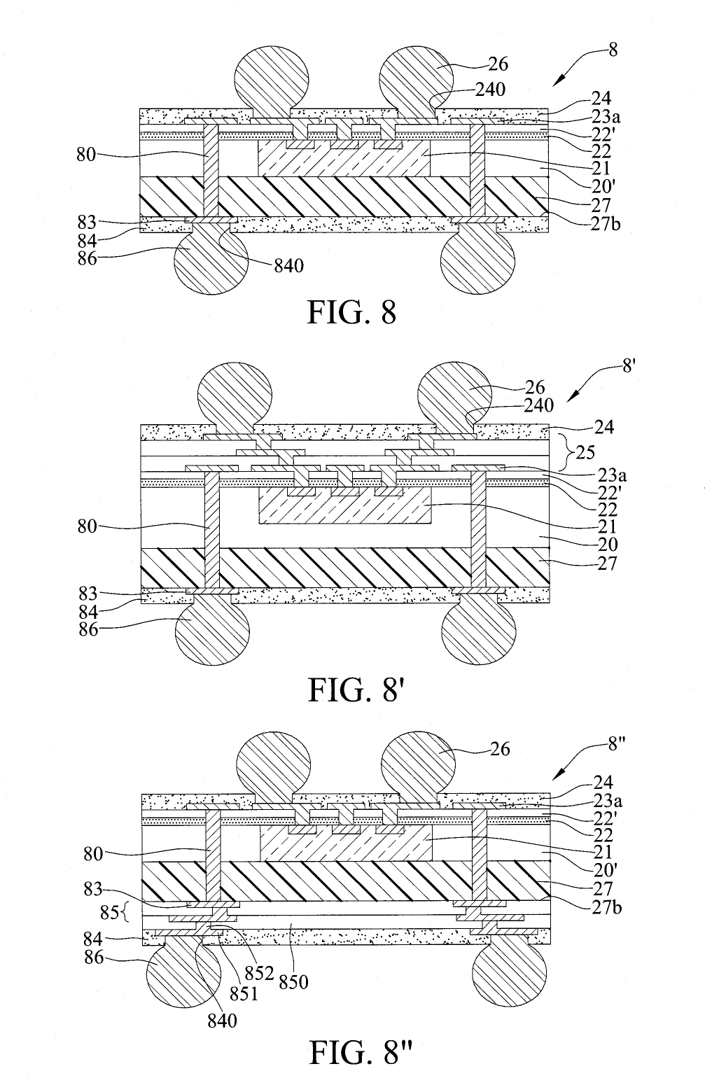

Referring to FIG. 8, the seventh embodiment differs from the fifth embodiment only in that a second circuit layer 83 is further formed in the seventh embodiment.

The second circuit layer 83 is formed on the fourth surface 27b of the hard layer 27. The package 8 further comprises conductive through holes 80 that penetrate the build-up dielectric layer 22′, the buffering dielectric layer 22, the encapsulating layer 20′ and the hard layer 27, and are electrically connected to the first and second circuit layers 23a, 83. Conductive blind vias (not shown) that electrically connect the second circuit layer 83 with the inactive surface 21b are formed in the hard layer 27.

The package 8 further comprises an insulating protective layer 24, 84 formed on the buffering dielectric layer 22 (or the build-up dielectric layer 22′), the first circuit layer 23a, the fourth surface 27b of the hard layer 27, and the second circuit layer 83. A plurality of holes 240, 840 that expose a portion of the first and second circuit layers 23a, 83, are formed on the insulating protective layer 24, 84, for conductive elements 26, 86 to be disposed on the first and second circuit layer 23a, 83 in the holes 240, 840.

Referring to FIG. 8′, in the package 8′ a build-up structure 25 electrically connected to the first circuit layer 23a is formed on the buffering dielectric layer 22 and the first circuit layer 23a only, an insulating protective layer 24 is formed on the build-up structure 25, and a plurality of holes 240 are formed in the insulating protective layer 24 for conductive elements 26 electrically connected to the build-up structure 25 to be disposed therein.

Referring to FIG. 8″, in the package 8″, a build-up structure 85 electrically connected to the second circuit layer 83 is formed on the fourth surface 27b of the hard layer 27 and the second circuit layer 83, an insulating protective layer 84 is formed on the build-up structure 85, and a plurality of holes 840 are formed in the insulating protective layer 84, for conductive elements 86 electrically connected to the build-up structure 85 to be disposed therein.

The build-up structure 85 comprises at least one build-up dielectric layer 850, another circuit layer 851 formed on the build-up dielectric layer 850, and another conductive blind vias 852 formed in the build-up dielectric layer 850 and electrically connected to the second circuit layer 83.

It is known from FIGS. 8′ and 8″ that the build-up structures 25, 85 are both formed on the buffering dielectric layer 22, the first circuit layer 23a, the fourth surface 27b of the hard layer 27, and the second circuit layer 83.

In conclusion, in the chip-scale package according to the present invention the buffering dielectric layer is formed on the encapsulating layer. With the excellent non-wetting property of the buffering dielectric layer with respect to the encapsulating layer, the buffering dielectric layer is evenly distributed on the encapsulating layer, and the expansion and evenness of the surfaces between layers are greatly improved.

Moreover, the solvent in the buffering dielectric layer does not cause damages to the encapsulating layer. Accordingly, the buffering dielectric layer is adhered to the encapsulating layer securely, and the chip-scale package according to the present invention may be improved reliability.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A chip-scale package, comprising:
an encapsulating layer having a first surface and a second surface opposing the first surface;
at least one chip embedded in the first surface of the encapsulating layer and having an active surface exposed from the first surface of the encapsulating layer, an inactive surface opposing the active surface, and a plurality of electrode pads disposed on the active surface;
a buffering dielectric layer formed on the first surface of the encapsulating layer and the active surface of the chip and having a plurality of openings for the electrode pads to be exposed therefrom;
a build-up dielectric layer formed on the buffering dielectric layer, the build-up dielectric layer and the buffering dielectric layer being made of different materials; and
a circuit layer formed on the build-up dielectric layer and having a plurality of conductive blind vias penetrating the build-up dielectric layer and being in communication with the openings of the buffering dielectric layer and electrically connected to the circuit layer and the electrode pads.

2. The chip-scale package of claim 1, wherein the encapsulating layer is made of packaging resin or soft material.

3. The chip-scale package of claim 2, wherein the soft material is Ajinomoto build-up film (ABF), bismaleimide-triacine (BT), polyimide (PI), polymerized siloxanes (silicone) or epoxy resin.

4. The chip-scale package of claim 1, wherein the second surface of the encapsulating layer is even with the inactive surface.

5. The chip-scale package of claim 1, wherein the first surface of the encapsulating layer is higher than the active surface of the chip.

6. The chip-scale package of claim 1, wherein the chip is an active element or a passive element.

7. The chip-scale package of claim 1, wherein the buffering dielectric layer is made of an inorganic silicon material or an organic polymer material.

8. The chip-scale package of claim 8, wherein the inorganic silicon material is SiO₂ or Si₃N₄, and the organic polymer material is parylene.

9. The chip-scale package of claim 1, wherein the buffering dielectric layer is formed on the first surface of the encapsulating layer and the active surface of the chip by a chemical vapor deposition process.

10. The chip-scale package of claim 1, further comprising an insulating protective layer formed on the build-up dielectric layer and the circuit layer, with a plurality of holes formed therethrough for exposing a portion of the circuit layer, and a conductive element electrically connected to the portion of the circuit layer.

11. The chip-scale package of claim 1, further comprising a build-up structure formed on the build-up dielectric layer and the circuit layer and electrically connected to the circuit layer.

12. The chip-scale package of claim 11, further comprising an insulating protective layer formed on the build-up structure, with a plurality of holes formed therethrough, and a conductive element formed in the holes and electrically connected to the build-up structure.

13. The chip-scale package of claim 1, further comprising a substrate having a fourth surface and a third surface opposing the fourth surface and attached to the second surface of the encapsulating layer and the inactive surface of the chip, a third circuit formed on the third surface for being embedded into the encapsulating layer, a fourth circuit formed on the fourth surface and electrically connected to the third circuit, and a plurality of conductive elements disposed on the third circuit and electrically connected to the circuit layer through the conductive blind vias.

14. The chip-scale package of claim 13, wherein the conductive elements are solder balls, pins, metal wires, metal bumps, or metal pillars.

15. The chip-scale package of claim 13, further comprising heat-dissipating pads disposed on the third circuit, for the inactive surface of the chip to be installed thereon.

16. The chip-scale package of claim 13, further comprising an insulating protective layer formed on the fourth circuit, with a plurality of holes formed in the insulating protective layer for exposing a portion of the fourth circuit.

17. The chip-scale package of claim 1, further comprising conductive bumps disposed in the encapsulating layer and electrically connected to the circuit layer through the conductive blind vias, the conductive bumps being coupled with the buffering dielectric layer and exposed from the second surface of the encapsulating layer.

18. The chip-scale package of claim 17, further comprising a plurality of holes formed in the encapsulating layer from the second surface thereof for exposing the conductive bumps.

19. The chip-scale package of claim 17, wherein the conductive bumps are even with the second surface of the encapsulating layer, allowing the conductive bumps to be exposed from the encapsulating layer.

20. The chip-scale package of claim 18, further comprising a metal layer formed on the exposed the conductive bumps.

21. The chip-scale package of claim 17, wherein the conductive bumps are made of copper.

22. The chip-scale package of claim 1, further comprising a metal structure layer formed on the second surface of the encapsulating layer.

23. The chip-scale package of claim 22, wherein the metal structure layer is further formed on the inactive surface of the chip.

24. The chip-scale package of claim 22, wherein the metal structure layer includes a first metal sublayer made of a chemical plating metal material or a sputtering metal material, and a second metal sublayer made of an electroplating metal material.

25. A chip-scale package, comprising:
an encapsulating layer having a first surface and a second surface opposing the first surface;
at least one chip embedded into the first surface of the encapsulating layer and having an active surface exposed from the first surface of the encapsulating layer, an inactive surface opposing the active surface, and a plurality of electrode pads disposed on the active surface of the chip;
a buffering dielectric layer formed on the first surface of the encapsulating layer and the active surface of the chip;
a build-up dielectric layer formed on the buffering dielectric layer, the build-up dielectric layer and the buffering dielectric layer being made of different materials;
a hard layer being harder than the encapsulating layer and having a third surface attached to the second surface of the encapsulating layer and a fourth surface opposing the third surface;
a first circuit layer formed on the build-up dielectric layer; and
a plurality of conductive blind vias penetrating the build-up dielectric layer and being in communication with the openings of the buffering dielectric layer and electrically connected to the first circuit layer and the electrode pads.

26. The chip-scale package of claim 25, wherein the encapsulating layer is made of packaging resin or soft material.

27. The chip-scale package of claim 26, wherein the soft material is Ajinomoto build-up film (ABF), bismaleimide-triacine (BT), polyimide (PI), polymerized siloxanes (silicone), or epoxy resin.

28. The chip-scale package of claim 25, wherein the encapsulating layer differs from the hard layer in more than five times of Young's modulus.

29. The chip-scale package of claim 25, wherein the chip is an active element or a passive elements.

30. The chip-scale package of claim 25, wherein the buffering dielectric layer is made of an inorganic silicon material or an organic polymer material.

31. The chip-scale package of claim 30, wherein the inorganic silicon material is SiO₂ or Si₃N₄, and the organic polymer material is parylene.

32. The chip-scale package of claim 25, wherein the buffering dielectric layer is formed on the first surface of the encapsulating layer and the active surface of the chip by a chemical vapor deposition process.

33. The chip-scale package of claim 25, wherein the hard layer is made of a solder mask material, epoxy resin, epoxy resin-contained ink, polyimide, silicon material, metal, prepreg, or copper foil substrate.

34. The chip-scale package of claim 25, wherein the inactive surface of the chip is even with the second surface of the encapsulating layer.

35. The chip-scale package of claim 25, further comprising a die attach film disposed between the inactive surface of the chip and the hard layer.

36. The chip-scale package of claim 25, wherein the third surface of the hard layer is further attached to the inactive surface of the chip.

37. The chip-scale package of claim 25, wherein the first surface of the encapsulating layer is higher than the active surface of the chip.

38. The chip-scale package of claim 25, further comprising an insulating protective layer formed on the build-up dielectric layer and the first circuit layer, with a plurality of holes formed therethrough for exposing a portion of the first circuit layer, and a plurality of conductive elements electrically connected to the first circuit layer in the holes.

39. The chip-scale package of claim 25, further comprising a build-up structure formed on the build-up dielectric layer and the first circuit layer and electrically connected to the first circuit layer.

40. The chip-scale package of claim 39, further comprising an insulating protective layer formed on the build-up structure, with a plurality of holes formed therethrough, and a plurality of conductive elements disposed in the holes and electrically connected to the build-up structure.

41. The chip-scale package of claim 25, further comprising a reinforced protective layer formed between the second surface of the encapsulating layer and the third surface of the hard layer.

42. The chip-scale package of claim 41, wherein the reinforced protective layer is made of epoxy resin.

43. The chip-scale package of claim 25, further comprising a second circuit layer formed on the fourth surface of the hard layer, and a plurality of conductive through holes penetrating the buffering dielectric layer, the build-up dielectric layer, the encapsulating layer, and the hard layer and electrically connected to the first circuit layer and the second circuit layer.

44. The chip-scale package of claim 43, further comprising an insulating protective layer formed on the build-up dielectric layer, the first circuit layer, the fourth surface of the hard layer, and the second circuit layer, with a plurality of holes formed therethrough for exposing portions of the first and second circuit layers, and a plurality of conductive elements disposed on the exposed portions of the first and second circuit layers in the holes.

45. The chip-scale package of claim 43, further comprising a build-up structure formed on the build-up dielectric layer and the first circuit layer, on the fourth surface of the hard layer and the second circuit layer, or on the buffering dielectric layer, the first circuit layer, the fourth surface of the hard layer, and the second circuit layer.

46. The chip-scale package of claim 45, further comprising an insulating protective layer formed on the build-up structure, with a plurality of holes formed therethrough for a plurality of conductive elements to be disposed in the holes.

47. The chip-scale package of claim 46, wherein the build-up structure is formed on the build-up dielectric layer and the first circuit layer, the insulating protective layer is further formed on the fourth surface of the hard layer and the second circuit layer, the holes further expose a portion of the second circuit layer, and the conductive elements are further disposed on the second circuit layer in the holes.

48. The chip-scale package of claim 46, wherein the build-up structure is formed on the fourth surface of the hard layer and the second circuit layer only, the insulating protective layer is further formed on the build-up dielectric layer and the first circuit layer, the holes further expose a portion of the first circuit layer, and the conductive elements are further disposed on the first circuit layer in the holes.
